(19) United States
(12) Patent Application Publication
(10) Pub. No.: US 2008/0048184 A1
(43) Pub. Date: Feb. 28, 2008

(54) METHOD OF FORMING CONTACT FOR ORGANIC ACTIVE LAYER, METHOD OF MANUFACTURING FLAT PANEL DISPLAY, ORGANIC THIN FILM TRANSISTOR DISPLAY, AND ORGANIC LIGHT EMITTING DIODE DISPLAY

(75) Inventors: Joon-Hak OH, Yongin-si (KR); Bo-Sung KIM, Seoul (KR); Seong-Sik SHIN, Seongnam-si (KR); Min-Ho YOON, Seoul (KR); Young-Soo YOON, Namyangju-si (KR); Seung-Hyun JEE, Yangpyeong-gun (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 11/845,402

(22) Filed: Aug. 27, 2007

(30) Foreign Application Priority Data
Aug. 25, 2006 (KR) 10-2006-0080907

(51) Int. Cl. H01L 51/00; H01L 51/40

(52) U.S. Cl. 257/40; 438/99; 257/E51.001

(57) ABSTRACT

A method for forming a contact of an organic active layer is provided. In this method, a transparent conductive oxide thin film is formed on a substrate, and a surface of the oxide thin film is activated by inducing a base —OH and an oxide —O. Then, the oxide thin film is washed with a hydrophobic material after activating the surface. A self-assembled monolayer is formed on the oxide thin film after washing, and an organic active layer is formed on the self-assembled monolayer. A method for manufacturing a flat panel display including formation of the contact, and an organic thin film transistor display panel and an organic light emitting diode display including the contact are also provided.

This application claims priority to Korean patent application no. 10-2006-0080907, filed on Aug. 25, 2006 and all the benefits accruing therefrom under 35 U.S.C. §119, the contents of which in its entirety are herein incorporated by reference.

### BACKGROUND OF THE INVENTION

(a) Field of the Invention

The present invention relates to a method of forming a contact for an organic active layer, a method of manufacturing a flat panel display including the organic active layer, an organic thin film transistor (“TFT”) display, and an organic light emitting diode (“OLED”) display. More particularly, the present invention relates to a method of forming a contact for an organic active layer that improves performance of a display device including the contact, a method of manufacturing a flat panel display having the contact, and an organic TFT display and an OLED display having the contact.

(b) Description of the Related Art

Recently, an organic active layer has been commonly used for an active matrix flat panel display such as a liquid crystal display (“LCD”) or an organic light emitting device (“OLED”).

In the case of the OLED, an organic material is used as an emission layer. In the case of an active matrix flat panel display, an organic semiconductor has been actively researched as an active layer of a transistor.

It is preferable to use a material having a high work function for an electrode contacting the organic active layer, and more particularly for an electrode for injecting holes. Accordingly, indium tin oxide (“ITO”) is widely used because ITO has a comparatively high work function, high transparency, and low sheet resistance, and it is easy to form a pattern with it.

However, the work function of ITO is not sufficiently high compared to certain other materials.

Recently, there has been research in progress for improving a work function by changing characteristics of a surface of an ITO thin film through a dry process, such as radiating ultraviolet rays or performing an oxygen plasma process. However, such methods require expensive equipment such as vacuum equipment, and the increment of work function is small. That is, it requires an inordinate cost compared to the effect thereof.

### BRIEF SUMMARY OF THE INVENTION

The present invention provides a method of forming a contact for an organic active layer, and a method of manufacturing a flat panel display including an organic active layer having advantages of improving the performance of the flat display device by increasing the work function of an ITO thin film. The present invention also provides an organic thin film transistor (“TFT”) display and an organic light emitting diode (“OLED”) display that includes the ITO thin film having increased work function. Thus, the present invention provides a flat panel display having improved performance by increasing a work function of an ITO thin film connecting an organic active layer.

Exemplary embodiments of the present invention provide a method for forming a contact of an organic active layer. In this method, a transparent conductive oxide thin film is formed on a substrate, and a surface of the oxide thin film is activated by inducing a base —OH and an oxide —O. Then, the oxide thin film is washed with a hydrophobic material after activating the surface. A self-assembled monolayer (“SAM”) is formed on the oxide thin film after washing, and an organic active layer is formed on the SAM.

The method may further include rinsing the substrate after forming the SAM and before forming the organic active layer. In washing the oxide thin film, a mixed solution of methanol and chloroform may be used.

The conductive oxide may be ITO.

In activating the surface, the substrate may be processed by a mixed solution of hydrogen peroxide (H₂O₂), ammonia (NH₃), and distilled water (H₂O) in a ratio of about 1-3:1-3:1-7, such as 3:3:5. Processing the substrate may include immersing the substrate in the mixed solution for about 1 minute to 10 minutes. Alternatively, processing the substrate may include spreading the mixed solution on the substrate, and leaving the substrate with the mixed solution spread thereon for about 1 to 10 minutes.

The hydrophobic material may be isooctane.

Forming the SAM may include forming a solution formed by dissolving a SAM material with a terminal having a functional group of high electronegativity and another terminal having a functional group of high reactivity on a conductive oxide thin film in a solvent of methanol and chloroform, and immersing the substrate in the solution.

A mixing ratio of methanol and chloroform in the methanol and chloroform mixed solvent may be about 3:7. A concentration of the solution may be about 5 mM to 30 mM, such as about 10 mM.

The SAM material may include at least one of 4-chlorophenyl phosphonic acid, 3-nitrophenyl phosphonic acid, and 2-chloroethyl phosphonic acid. The SAM material may also include at least one of aryldihalophospate, substituted aryldihalophospate, arylsulfonyl halide, substituted arylsulfonyl halide, trihalophenylsilane, and substituted trihalophenylsilane.

The time of leaving the substrate immersed may be about 10 minutes to 20 minutes. A work function of the oxide thin film with the SAM formed thereon may be about 5.2 eV to 5.5 eV.

Another exemplary embodiment of the present invention provides a method for manufacturing a flat panel display. In this method, a control electrode is formed on a substrate, and an input electrode and an output electrode are formed on the substrate to be insulated from the control electrode. A pixel electrode is formed on the substrate to be insulated from the control electrode, and surfaces of the input and output electrodes and the pixel electrode are processed with a mixed solution of hydrogen peroxide (H₂O₂), ammonia (NF₃), and distilled water (H₂O). The processed input and output electrodes and pixel electrode are dried, and the dried input and output electrodes and pixel electrode are washed with a hydrophobic material. A SAM is formed on the washed input and output electrodes and the pixel electrode, and an organic active layer is formed on the SAM.

A work function of the input and output electrodes and the pixel electrode with the SAM may be about 5.2 eV to 5.5 eV.

The method may further include rinsing the substrate with a mixed solution of methanol and chloroform after forming the SAM and before forming the organic active layer.

The input and output electrodes and the pixel electrode may be an ITO thin film. A mixing ratio of the hydrogen peroxide (H₂O₂), ammonia (NH₃), and distilled water (H₂O) may be about 1-3:1-3:1-7, such as about 3:3:5.

Processing the surfaces of the input and output electrodes and the pixel electrode with the mixed solution may include immersing the substrate in the mixed solution for about 1 to 10 minutes. Alternatively, processing the surfaces of the input and output electrodes and the pixel electrode with the mixed solution may include spreading the mixed solution on the substrate and leaving the mixed solution on the substrate for about 1 to 10 minutes.

Forming the SAM may include forming a solution formed by dissolving a SAM material with a terminal having a functional group of high electronegativity and another terminal having a functional group of high reactivity on a conductive oxide thin film in a solvent of methanol and chloroform, and immersing the substrate in the solution. A mixing ratio of methanol and chloroform in the methanol and chloroform mixed solvent may be about 3:7. A concentration of the mixed solution may be about 5 mM to 30 mM.

The SAM material may include at least one of 4-chlorophenyl phosphonic acid, 3-nitrophenyl phosphonic acid, and 2-chloroethyl phosphonic acid. The SAM material may also include at least one of aryldihalophospate, substituted aryldihalophospate, arylsulfonyl halide, substituted arylsulfonyl halide, trihalophenylsilane, and substituted trihalophenylsilane.

The method may further include forming an insulating layer having an opening exposing an area of the input and output electrodes and the pixel electrode before processing the surfaces of the input and output electrodes and the pixel electrode with the mixed solution, wherein the organic active layer may be formed inside the opening.

The SAM may be located between the input and output electrodes and the organic active layer, and the organic active layer may be an organic semiconductor. The method may further include forming a data line on the substrate, and forming an interlayer insulating layer having a first contact hole for connecting the data line to the input electrode on the data line.

A gate line may be formed to be connected to the control electrode in the forming of the control electrode, and the output electrode may be integrally formed with the pixel electrode. In this case, the manufacturing method may further include forming an insulating layer having a second contact hole, exposing the first contact hole to connect the data line and the input electrode, and having an opening exposing the control electrode on the gate line and the interlayer insulating layer, and the insulating layer having the second contact hole and the opening formed below the input electrode and the output electrode, and forming a gate insulator on the control electrode and below the organic active layer within the opening.

The SAM may be located between the pixel electrode and the organic active layer, and the organic active layer may be an emission layer. In this case, the manufacturing method may further include forming a common electrode on the organic active layer. The method may further include forming an insulating layer on the control electrode, and below the input electrode and the output electrode, and forming a passivation layer having a contact hole to connect the output electrode to the pixel electrode on the input electrode, the output electrode, and the insulating layer, and below the pixel electrode. The method may further include forming a gate line including a first electrode on the same layer as the control electrode, forming a data line including a second electrode and forming a third electrode separated from the data line within a same layer as the input electrode and the output electrode, and forming a connecting member connecting the third electrode and the control electrode on a same layer as the pixel electrode.

Still another exemplary embodiment of the present invention provides an organic TFT display panel including a substrate, a data line, a gate line, an insulating layer, a gate insulator, an input electrode, a pixel electrode, a bank, and an organic semiconductor. The data line is formed on the substrate. The gate line crosses the data line and includes a control electrode. The insulating layer is formed on the gate line and the data line, and includes a first opening exposing the control electrode. The gate insulator is formed in the first opening, and the input electrode is formed on the gate insulator and connected to the data line. The pixel electrode is located on the gate insulator and includes an output electrode facing the input electrode. The bank is formed on the input electrode and the output electrode and defines a second opening exposing a portion of the input electrode and a portion of the output electrode. The organic semiconductor is formed in the second opening. The SAM is formed on a surface of the input electrode and the pixel electrode.

A work function of the input electrode and pixel electrode with the SAM may be about 5.2 eV to 5.5 eV.

The SAM may include at least one of 4-chlorophenyl phosphonic acid, 3-nitrophenyl phosphonic acid, and 2-chloroethyl phosphonic acid. The SAM material may include at least one of aryldihalophospate, substituted aryldihalophospate, arylsulfonyl halide, substituted arylsulfonyl halide, trihalophenylsilane, and substituted trihalophenylsilane.

Still other exemplary embodiments of the present invention provide an OLED display including a substrate, a pixel electrode, a common electrode, and an organic active layer. The pixel electrode is formed on the substrate. The common electrode faces the pixel electrode, and the organic active layer is located between the pixel electrode and the common electrode. A SAM is formed on a surface of the pixel electrode.

A work function of the pixel electrode with the SAM formed thereon may be about 5.2 eV to 5.5 eV.

The SAM may be formed of a material including at least one of 4-chlorophenyl phosphonic acid, 3-nitrophenyl phosphonic acid, and 2-chloroethyl phosphonic acid. The SAM material may be formed using a material having at least one of aryldihalophospate, substituted aryldihalophospate, arylsulfonyl halide, substituted arylsulfonyl halide, trihalophenylsilane, and substituted trihalophenylsilane.

### BRIEF DESCRIPTION OF THE DRAWINGS

FIG. 1 to FIG. 3 are schematic cross-sectional views illustrating an exemplary method of forming an exemplary organic active layer of contact according to an exemplary embodiment of the present invention;

FIG. 4 is a layout view illustrating an exemplary organic thin film transistor (“TFT”) array panel according to an exemplary embodiment of the present invention;

FIG. 5 is a cross-sectional view of the exemplary organic TFT array panel of FIG. 4 taken along line V-V according to an exemplary embodiment of the present invention;

FIG. 6 is a cross-sectional view of the exemplary organic TFT array panel of FIG. 4 taken along line V-V according to another exemplary embodiment of the present invention;

FIG. 7, FIG. 9, FIG. 11, FIG. 13, and FIG. 15 are layout views of the exemplary organic TFT array panel of FIG. 4, FIG. 5, and FIG. 6 for describing an exemplary manufacturing method according to an exemplary embodiment of the present invention;

FIG. 8 is a cross-sectional view of the exemplary organic TFT array panel of FIG. 7 taken along line VIII-VIII;

FIG. 10 is a cross-sectional view of the exemplary organic TFT array panel of FIG. 9 taken along line X-X;

FIG. 12 is a cross-sectional view of the exemplary organic TFT array panel of FIG. 11 taken along line XII-XII;

FIG. 14 is a cross-sectional view of the exemplary organic TFT array panel of FIG. 13 taken along line XIV-XIV;

FIG. 16 is a cross-sectional view of the exemplary organic TFT array panel of FIG. 15 taken along line XVI-XVI;

FIG. 17 is a layout view of an exemplary organic light emitting diode (“OLED”) display according to an exemplary embodiment of the present invention;

FIG. 18 is a cross-sectional view illustrating the exemplary OLED display of FIG. 17 taken along line XVIII-XVIII; and,

FIG. 19 and FIG. 20 are cross-sectional views illustrating the exemplary OLED display of FIG. 17 taken along line XIX-XIX.

### DETAILED DESCRIPTION OF THE INVENTION

Exemplary embodiments of the present invention will now be described in detail with reference to the accompanying drawings in order for those skilled in the art to easily practice the present invention. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

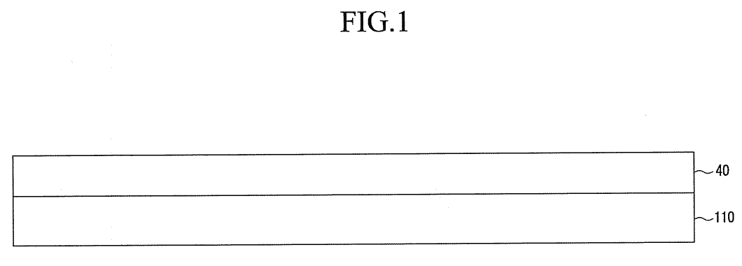

A method of forming a contact of an organic active layer according to an exemplary embodiment of the present invention will now be described with reference to FIG. 1 to FIG. 3.

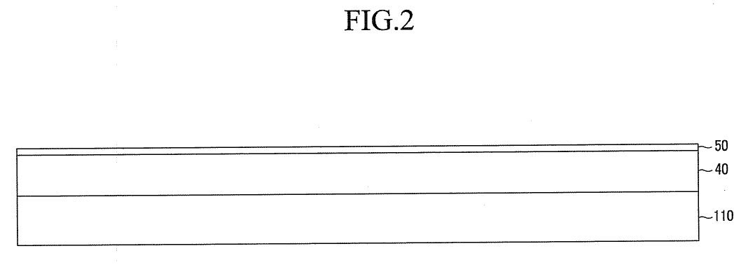

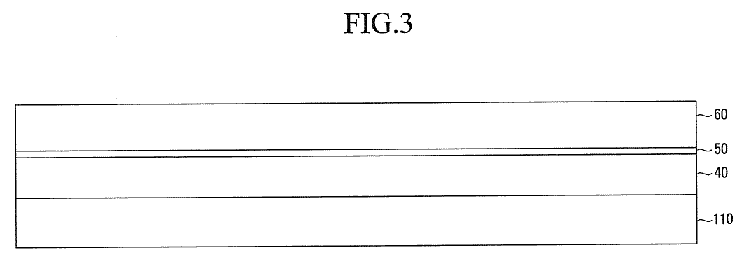

Referring to FIG. 1, an indium tin oxide (“ITO”) thin film 40 is formed on a substrate 110, and the surface of the ITO film 40 is activated. Referring to FIG. 2, a self-assembled monolayer (“SAM”) 50 is formed by surface-treating the activated ITO thin film 40. As shown in FIG. 3, an organic active layer 60 is formed on the SAM 50.

The above process will now be described in further detail.

The surface activation of the ITO thin film 40 facilitates the adhesion of the SAM 50 by inducing a base —OH and an oxide —O into the surface of the ITO thin film 40.

For example, the substrate 110 including the ITO thin film 40 is soaked in a solution for about 1 to 10 minutes, which is mixed with hydrogen peroxide (H₂O₂), ammonia (NH₃), and distilled water (H₂O) in the ratio of 1-3:1-3:1-7, i.e. in the range of about 1:1:1 to about 3:3:7, and preferably 3:3:5. Alternatively, the substrate 110 may be maintained with the solution sprayed thereon for about 1 to 10 minutes as it is.

Thereafter, the substrate 110 is dried by using a spin dry method, or with an air blower that emits a gas such as nitrogen N or argon Ar.

Next, the surface of the ITO thin film 40 is secondly washed with a hydrophobic material such as isooctane (2,2,4-Trimethylpentane).

The SAM 50 is formed by surface-treating the ITO thin film 40 with the SAM material.

The SAM material has a functional group with high electronegativity on one terminal and a functional group having good reactivity to ITO on the other terminal.

A phosphonic acid-based SAM material such as 4-chlorophenyl phosphonic acid, 3-nitrophenyl phosphonic acid, or 2-chloroethyl phosphonic acid is dissolved in a solvent that is mixed with methanol and chloroform, making a solution having a concentration of about 5 to 30 mM, and preferably about 10 mM. It is desired that the mixing ratio of methanol and chloroform is about 3:7.

Other examples of the SAM material are aryldihalophospate, substituted aryldihalophospate, arylsulfonyl halide, substituted arylsulfonyl halide, trihalophenylsilane, substituted trihalophenylsilane, and so on.

The substrate 110 including the ITO thin film 40 is put into the solution of the SAM material and the solvent for about 10 to 20 minutes, or is maintained with the solution sprayed thereon for about 10 to 20 minutes.

Then, the surface of the ITO thin film 40 is rinsed with methanol and chloroform.

As a result, the SAM 50 is formed on the surface of the ITO thin film 40, as shown in FIG. 2.

As described above, an ohmic contact with no barrier between the ITO thin film 40 and the organic active layer 60 can be made by activating the surface of the ITO thin film 40, forming the SAM 50, and forming the organic active layer 60 on the SAM 50. This makes hole injection from the ITO thin film 40 to the organic active layer 60 easy.

To measure the increase of work function of the ITO thin film 40 including the SAM 50, an experiment was performed as described below.

First, the surface of the ITO thin film 40 was washed with a solution of hydrogen peroxide (H₂O₂), ammonia (NH₃), and distilled water (H₂O), and secondly washed with isooctane. Then, 4-chlorophenyl phosphonic acid, 3-nitrophenyl phosphonic acid, and 2-chloroethyl phosphonic acid were each dissolved in a mixed solvent of methanol and chloroform in a ratio of about 3:7, each making a solution having a concentration of 10 mM. The substrate 110 having the ITO thin film 40 thereon was soaked in each solution for about 10 minutes and the work function of the ITO thin film 40 was measured with a Kelvin probe, and the results are shown in Table 1.

TABLE 1

| | | Solution | Work | Work |
|---|---|---|---|---|
| | Processing | Concen- | Function | Function |
| SAM material | Time | tration | (eV) | Increase (eV) |
| 4-chlorophenyl | 10 min | 10 mM | 5.232 | 0.635 |
| phosphonic acid | | | | |
| 3-nitrophenyl | 10 min | 10 mM | 5.206 | 0.609 |
| phosphonic acid | | | | |
| 2-chloroethyl | 10 min | 10 mM | 5.482 | 0.885 |
| phosphonic acid | | | | |
| ITO thin film before | — | — | 4.597 | — |
| surface modification | | | | |

As shown in Table 1, the work function of the ITO thin film 40 before the surface modification was about 4.5 eV, and the work function of the ITO thin film 40 after performing surface modification with the SAM 50 was about 5.2 to 5.5 eV. Since the work function of the organic semiconductor that is mainly used as a material for an organic active layer 60 is 5.2 to 5.5 eV, an ohmic contact having no energy barrier between the ITO thin film 40 and the organic active layer 60 can be made.

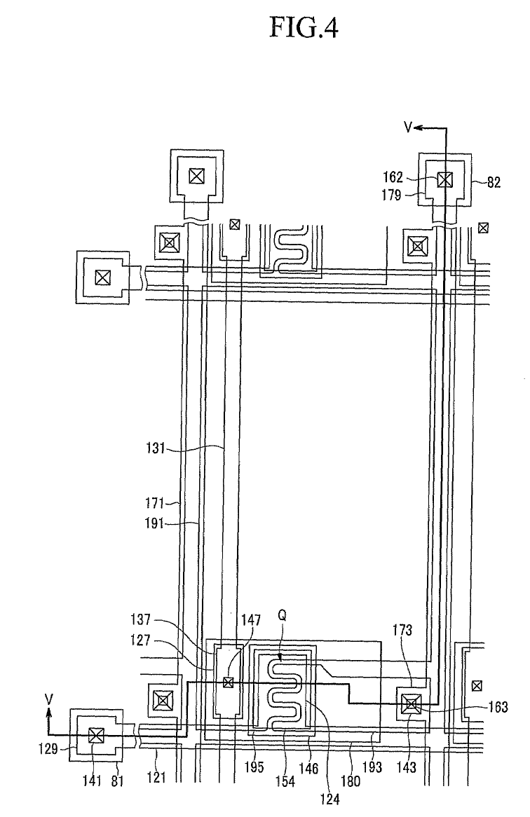

An organic thin film transistor (“TFT”) array panel according to an exemplary embodiment of the present invention will now be described in detail with reference to FIGS. 4 to 6.

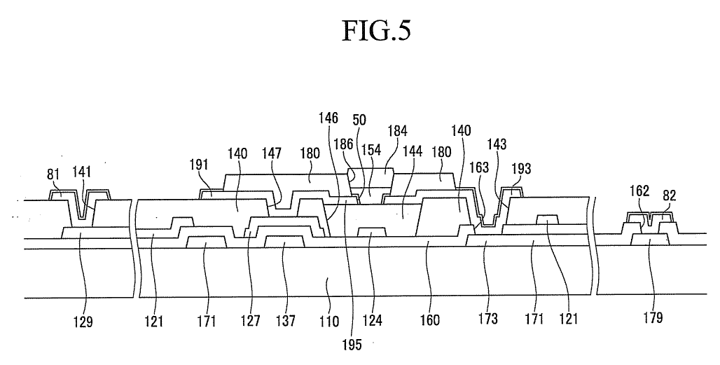

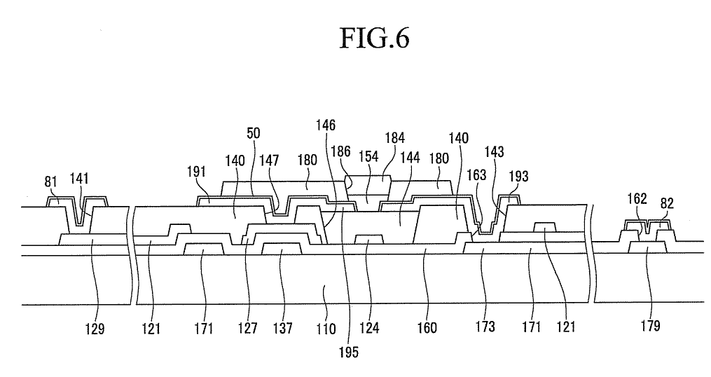

FIG. 4 is a layout view of an exemplary organic TFT array panel according to an exemplary embodiment of the present invention. FIG. 5 is an exemplary cross-sectional view of the exemplary organic TFT array panel taken along line V-V of FIG. 4, and FIG. 6 is another exemplary cross-sectional view of the exemplary organic TFT array panel taken along line V-V of FIG. 4.

A plurality of data lines 171 and a plurality of storage electrode lines 131 are formed on an insulation substrate 110 made of transparent glass, silicon, plastic, or the like.

The data lines 171 transfer data signals and extend basically in a vertical direction, such as a second direction. The data lines 171 include a plurality of projections 173 protruded sideward, towards adjacent data lines 171, and wide ends 179 for connecting with other layers or external driving circuits. A data driving circuit (not shown) for generating data signals may be mounted on a flexible printed circuit (“FPC”) film (not shown) attached to the substrate 110 or mounted directly on the substrate 110, or may be integrated with the substrate 110. If the data driving circuit is integrated with the substrate 110, it may be directly connected to the data lines 171.

The storage electrode lines 131 receive a predetermined voltage and extend to run almost parallel to the data lines 171 in the second direction. Each of the storage electrode lines 131 is disposed between two adjacent data lines 171 and, as illustrated, is placed closer to the left one of the two adjacent data lines 171. The storage electrode lines 131 include storage electrodes 137 protruded sideward. As illustrated, the storage electrodes 137 may protrude towards both adjacent data lines 171. While a particular arrangement has been described, the shape and disposition of the storage electrode lines 131 may be variously changed.

The data lines 171 and storage electrode lines 131 are made of an aluminum —Al group metal including Al of an Al alloy, a silver —Ag group metal including Ag or a Ag alloy, a copper —Cu group metal including Cu or a Cu alloy, a molybdenum —Mo group metal including Mo or a Mo alloy, chromium Cr, tantalum Ta, or titanium Ti. However, they may have a multi-layered structure including two conductive layers (not shown) that have different physical properties from each other. In such a multi-layered structure, one of the two conductive layers may be made of a low-resistive metal to reduce voltage drop, such as an Al-group metal, a Ag-group metal, and a Cu-group metal, while the other conductive layer may be made of a material that has excellent physical, chemical, and electrical contact characteristics with other materials, particularly indium tin oxide (“ITO”) and indium zinc oxide (“IZO”), for example a Mo-group metal, chromium, tantalum, and titanium. An exemplary combination may include a combination of a chromium lower layer and an aluminum (alloy) upper layer, and a combination of an aluminum (alloy) lower layer and molybdenum (alloy) upper layer. While particular examples have been provided, it should be understood that the data lines 171 and storage electrode lines 131 may be made of various other metals or conductors.

The sides of the data lines 171 and storage electrode lines 131 are inclined relative to the surface of the substrate 110, and it is desirable that the inclination angle is about 30 to about 80 degrees.

An interlayer insulating layer 160 is formed on the data lines 171 and the storage electrode lines 131, as well as on the exposed surfaces of the substrate 110. The interlayer insulating layer 160 may be made of an inorganic insulator or an organic insulator. The inorganic insulator may be silicon nitride (SiNₓ) or silicon oxide (SiO₂).

A plurality of contact holes 162 and 163 are formed on the interlayer insulating layer 160 to expose the ends 179 and projections 173 of the data lines 171, respectively.

A plurality of gate lines 121 and a plurality of storage conductors 127 are formed on the interlayer insulating layer 160.

The gate lines 121 transfer gate signals and extend basically in a horizontal direction, a first direction, to cross the data lines 171. The second direction may be substantially perpendicular to the first direction. The gate lines 121 include a plurality of control electrodes 124 protruded upward towards an adjacent gate line 121 and wide ends 129 for connecting with other layers or external driving circuits. A gate driving circuit (not shown) for generating gate signals may be mounted on an FPC film (not shown) attached to the substrate 110 or mounted directly on the substrate 110, or may be integrated with the substrate 110. If the gate driving circuit is integrated with the substrate 110, it may be directly connected to the gate lines 121.

The storage conductors 127 are separated from the gate lines 121 and are overlapped with the storage electrodes 137.

The gate lines 121 and the storage conductors 127 may be made of the same material as that of the data lines 171 and the storage electrode lines 131. The sides of the gate lines 121 and the storage conductors 127 are also inclined relative to the surface of the substrate 110, and it is desirable that the inclination angle is about 30 to about 80 degrees.

An insulating layer 140 is formed on the gate lines 121 and storage conductors 127, as well as on at least some of the exposed surfaces of the interlayer insulating layer 160. The insulating layer 140 is made of an organic material or an inorganic material. The organic material may be a polyacryl-based compound, a polystyrene-based compound, or a soluble polymer such as benzocyclobutane (“BCB”). The inorganic material may be silicon nitride or silicon oxide. The insulating layer 140 may be removed from or not formed on the ends 179 of the data lines 171 and on the interlayer insulating layer 160 surrounding the ends 179. This can prevent the insulating layer 140 and the interlayer insulating layer 160 formed on the ends 179 of the data lines 171 from separating from each other due to poor adhesion, and allows the ends 179 of the data lines 171 and external circuits to be effectively connected.

A plurality of openings 146 to expose the control electrodes 124, a plurality of contact holes 141 to expose the ends 129 of the gate lines 121, a plurality of contact holes 143 to expose the contact holes 163 and the projections 173 of the data lines 171, and a plurality of contact holes 147 to expose the storage conductors 127 are formed through the insulating layer 140.

A gate insulator 144 is formed in the openings 146 of the insulating layer 140. The gate insulator 144 covers the control electrodes 124 and may further overlap a portion of the interlayer insulating layer 160 surrounding the control electrodes 124. The sidewalls of the openings 146 are higher than the gate insulator 144 so that the insulating layer 140 functions as a bank, and the size of the openings 146 is large enough to level the surface of the gate insulator 144.

The gate insulator 144 is made of an organic material or an inorganic material. The organic material may be a polyimide-based compound, a polyvinyl alcohol-based compound, a polyfluorane-based compound, a soluble polymer such as parylene, and the like. The inorganic material may be silicon oxide and the like, which is surface-treated with octadecyl trichloro silane (“OTS”).

A plurality of pixel conductors including a plurality of input electrodes 193, a plurality of pixel electrodes 191, and a plurality of contact assistants 81 and 82 are formed on the insulating layer 140 and gate insulator 144. The pixel conductors 81, 82, 191, and 193 may be made of a transparent conductive material such as ITO and the like.

The input electrodes 193 are connected to the projections 173 of the data lines 171 through the contact holes 143 and 163 and extend above a portion of the control electrodes 124.

The pixel electrodes 191 are connected to the storage conductors 127 through the contact holes 147, and include output electrodes 195 facing the input electrodes 193 with the control electrodes 124 there between on the gate insulator 144. Each pair of the facing sides of the output electrodes 195 and input electrodes 193 are parallel to each other and may run meanderingly. That is, the facing sides of the input and output electrodes 193 and 195 may have serpentine edges such that a gap between the input and output electrodes 193 and 195 is substantially the same throughout the gap. The pixel electrodes 191 overlap with the gate lines 121 and data lines 171 to increase the aperture ratio.

The contact assistants 81 and 82 are connected to the ends 129 of the gate lines 121 and the ends 179 of the data lines 171 through the contact holes 141 and 162, respectively. The contact assistants 81 and 82 supplement the connectivity of the ends 129 of the gate lines 121 and the ends 179 of the data lines 171 with external devices, and protect them.

The SAM 50 is formed on the pixel conductors 81, 82, 191, and 193. The SAM 50 is made by the surface modification of the pixel conductors 81, 82, 191, and 193, and is made of a phosphonic acid-based SAM material having a functional group with high electronegativity on one terminal and a functional group with good reactivity to the pixel conductors 81, 82, 191, and 193 on the other terminal. While it is formed on a part of the input electrodes 193, a part of the pixel electrodes 191, and the entire contact assistants 81 and 82 in the exemplary embodiment shown in FIG. 5, the SAM 50 is formed on the entire pixel conductors 81, 82, 191, and 193 in the exemplary embodiment shown in FIG. 6.

A plurality of insulating banks 180 are formed on the input electrodes 193, the pixel electrodes 191, the gate insulator 144, and the insulating layer 140. The banks 180 may be made of a photosensitive organic material that allows a solution process.

A plurality of openings 186 are formed through the banks 180. The openings 186 are aligned over the gate insulator 144 and the control electrodes 124 in the openings 146 of the insulating layer 140 to expose parts of the input electrodes 193 and output electrodes 195 and the region of the gate insulator 144 between the two electrodes 193 and 195. The openings 186 of the banks 180 are smaller than the openings 146 of the insulating layer 140. Therefore, the banks 180 can fix the gate insulator 144 firmly so as to prevent the gate insulator 144 from lifting and to reduce permeation by chemical solution in the manufacturing process.

A plurality of organic semiconductor islands 154 are formed in the openings 186 of the banks 180 on the SAM 50 and on the exposed portion of the gate insulator 144. The organic semiconductors 154 adjoin the input electrodes 193 and output electrodes 195 on the top of the control electrodes 124, and are lower than the banks 180 in height so as to be completely confined in the banks 180. Since the organic semiconductors 154 are completely confined within the banks 180 so as not to expose any sides, it is possible to prevent a chemical solution from permeating through the sides of the organic semiconductors 154 in the manufacturing process.

The organic semiconductors 154 may include high or low molecular compounds that are dissolved in aqueous solutions or organic solvents, and may be formed by inkjet printing. The organic semiconductors 154 may also be formed by using another solution process such as spin coating, slit coating, and the like, or by chemical or physical vapor deposition methods. In this case, the banks 180 can be omitted.

The organic semiconductors 154 may include derivatives having substituents of tetracene or pentacene. The organic semiconductors 154 may also include oligothiophenes including 4 to 8 thiophenes connected to thiophene rings at the 2 and 5 positions.

The organic semiconductors 154 may include polythienylenevinylene, poly-3-hexylthiophene, polythiophene, phthalocyanine, metalized phthalocyanine, or halogenized derivatives thereof. The organic semiconductors 154 may also include perylenetetracarboxylic dianhydride (“PTCDA”), naphthalenetetracarboxylic dianhydride (“NTCDA”), or imide derivatives thereof. The organic semiconductors 154 may further include perylene, coronene, and derivatives having substituents thereof.

An organic TFT (“OTFT”) Q includes one control electrode 124, one input electrode 193, and one output electrode 195 together with the organic semiconductor 154, and the channel of the OTFT Q is formed in the organic semiconductor 154 between the input electrode 193 and the output electrode 195.

As described above, the SAM 50 is formed on the input electrodes 193, pixel electrodes 191, and contact assistants 81 and 82. In the case of FIG. 5, the SAM 50 is provided on the regions that are not covered with the banks 180, and is particularly provided on the regions that contact the organic semiconductors 154 on the input electrodes 193 and output electrodes 195. Since the work function difference between the organic semiconductor 154 and the material for the input electrodes 193 and output electrodes 195 is small, the hole injection from the electrodes 193 and 195 to the organic semiconductors 154 is relatively easy. In addition, the SAM 50 between the organic semiconductors 154 and the input and output electrodes 193 and 195 can further reduce such a work function difference to further facilitate the hole injection from the input and output electrodes 193 and 195 to the organic semiconductors 154. Therefore, the performance of the OTFT Q can improve.

The pixel electrodes 191 receive a data voltage from the OTFT Q and generate electric fields together with common electrodes (not shown) of another display panel (not shown) on which a common voltage is applied so as to determine the direction of liquid crystal molecules of the liquid crystal layer (not shown) between the pixel electrodes and the common electrode. The pixel electrodes 191 and the common electrode form capacitors (hereinafter referred to as “liquid crystal capacitors”) to maintain the applied voltage even after the OTFT Q is turned off.

Blocking members 184 are formed on the organic semiconductors 154. The blocking members 184 are made of fluorine based hydrocarbon compounds, polyvinylalcohol-based compounds, and the like and protect the organic semiconductors 154 from outside heat, plasma, or chemical materials.

Another passivation layer (not shown) may be formed on the blocking members 184, the OTFT Q, and the banks 180 to enhance the protecting function for the organic semiconductors 154.

Although the OTFT is shown as an example in FIGS. 4 to 6, the present invention can also be applied to different types of OTFTs.

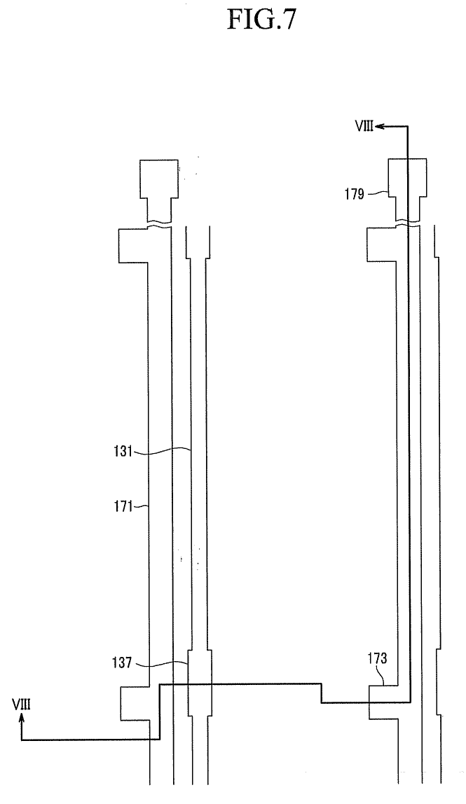

An exemplary method of manufacturing the exemplary organic TFT array panel shown in FIG. 4 to FIG. 6 according to an exemplary embodiment of the present invention will now be described in detail with reference to FIG. 7 to FIG. 16, and with further reference to FIG. 4 to FIG. 6.

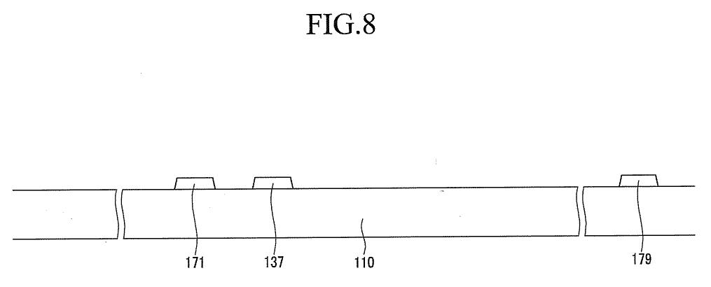

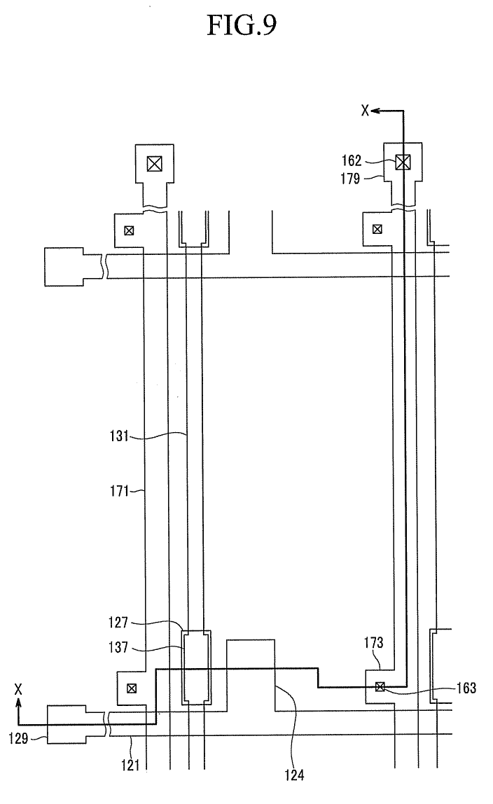

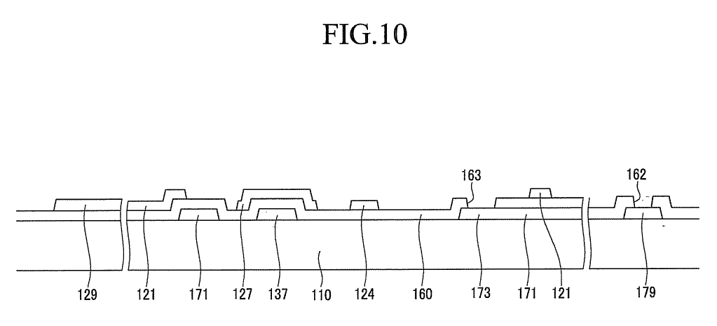

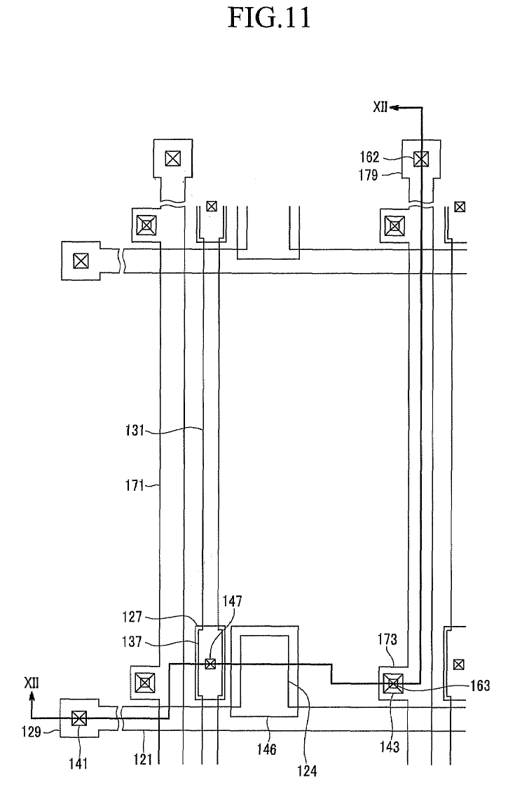

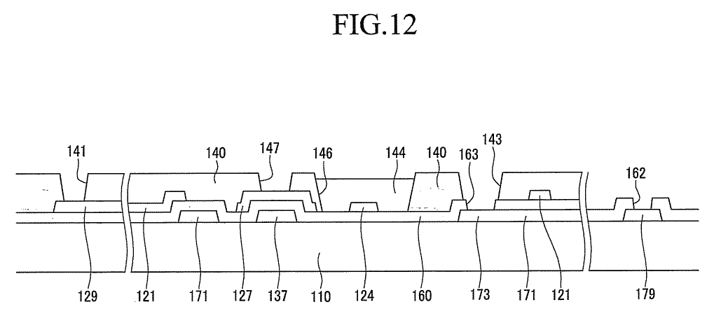

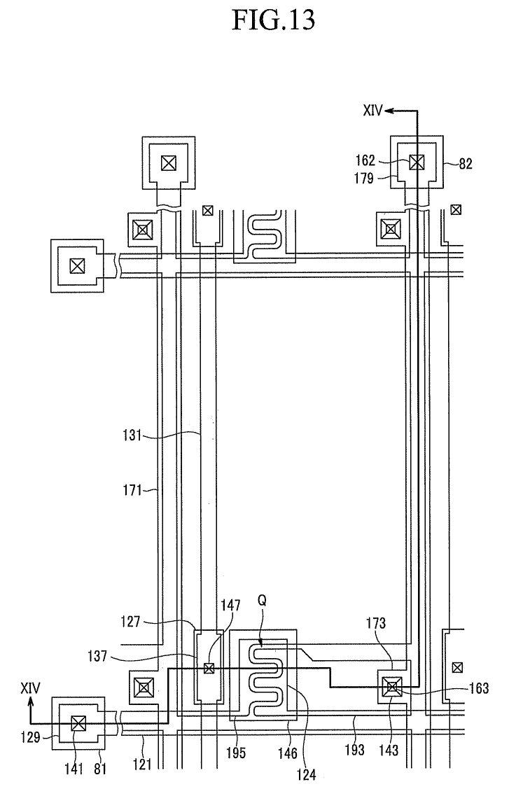

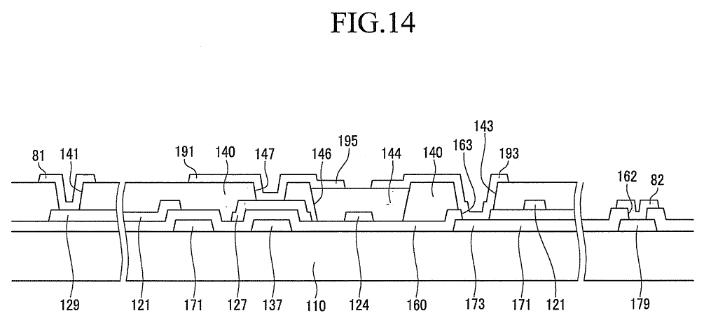

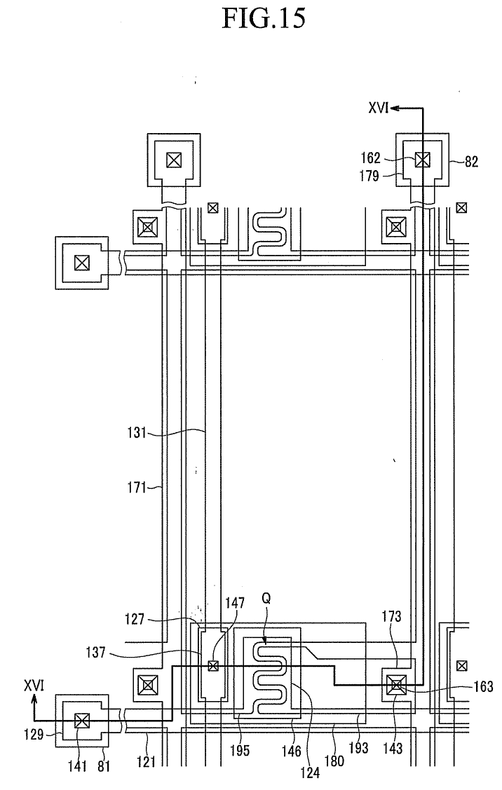

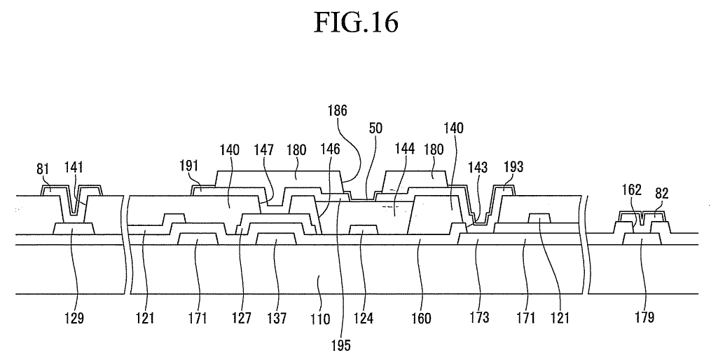

FIG. 7, FIG. 9, FIG. 11, FIG. 13, and FIG. 15 are layout views each illustrating one of the exemplary stages of manufacturing the exemplary organic TFT array panel shown in FIG. 4, FIG. 5, and FIG. 6 according to an exemplary embodiment of the present invention. FIG. 8 is a cross-sectional view of the exemplary organic TFT array panel taken along line VIII-VIII of FIG. 7, FIG. 10 is a cross-sectional view of the exemplary organic TFT array panel taken along line X-X of FIG. 9, and FIG. 12 is a cross-sectional view of the exemplary organic TFT array panel taken along line XII-XII of FIG. 11. FIG. 14 is a cross-sectional view of the exemplary organic TFT array panel taken along line XIV-XIV of FIG. 13, and FIG. 16 is a cross-sectional view of the exemplary organic TFT array panel taken along line XVI-XVI of FIG. 15.

First, a plurality of storage electrode lines 131 including storage electrodes 137 and a plurality of data lines 171 each having a projection 173 and an end 179 as shown in FIG. 7 and FIG. 8 are formed by stacking a metal layer on a substrate 110 using a sputtering method and the like and performing photolithography on the layer.

Then, an interlayer insulating layer 160 having contact holes 162 and 163 is formed using chemical vapor deposition (“CVD”) on an inorganic material or by spin coating on an organic material. If the interlayer insulating layer 160 is made of an inorganic material, the contact holes 162 and 163 can be formed through a photolithography process using a photosensitive film. If the interlayer insulating layer 160 is a photosensitive organic material, the contact holes 162 and 163 can be formed only by a photolithography process.

Referring to FIG. 9 and FIG. 10, the metal layer is stacked on the interlayer insulating layer 160 and is photolithographed, forming a plurality of gate lines 121 each having a control electrode 124 and an end 129, and a plurality of storage conductors 127.

Referring to FIG. 11 and FIG. 12, an insulating layer 140 having an opening 146 and contact holes 141, 143, and 147 is formed by spin coating and patterning a photosensitive organic material on the gate lines 121, the storage conductors 127, and exposed portions of the interlayer insulating layer 160. At this time, the organic material of the insulating layer 140 around the end 179 of the data line 171 should be removed.

Next, a plurality of gate insulators 144 is formed in the openings 146 of the insulating layer 140 using an inkjet printing method. In the case of using the inkjet printing method, the gate insulator 144 is formed by dripping a solution into each opening 146 and drying it. The present invention, however, is not limited thereto. Various solution processes such as spin coating and slit coating can alternatively be used.

Referring to FIG. 13 and FIG. 14, a plurality of pixel conductors including a plurality of pixel electrodes 191 having output electrodes 195, a plurality of input electrodes 193, and a plurality of contact assistants 81 and 82 are formed by sputtering amorphous ITO and performing a photolithography process thereto.

It is preferable that the sputtering temperature is a low temperature, particularly room temperature, and for example about 25° C. to 130° C., and that the amorphous ITO is etched using a weak basic etchant. This can prevent the gate insulator 144 and the insulating layer 140 made of an organic material from being damaged by heat and chemical solution.

Referring to FIG. 15 and FIG. 16, a plurality of banks 180 having openings 186 are formed by applying a photosensitive organic layer and developing it. The banks 180 are present only on parts of the input electrodes 193 and pixel electrodes 191, and the openings 186 expose parts of the input electrodes 193 and output electrodes 195, particularly meandering sides, the facing sides, of the input electrodes 193 and output electrodes 195 facing each other.

Referring to FIG. 16, a SAM 50 is formed on the exposed regions of the gate insulator 144, the pixel electrodes 191, the input electrodes 193, and the contact assistants 81 and 82. This will now be described in detail.

First, the surface of the exposed regions of the pixel conductors 81, 82, 191, and 193 is activated. For example, the substrate 110, including the elements disposed thereon, is put into a solution mixed with hydrogen peroxide (H₂O₂), ammonia (NH₃), and distilled water (H₂O) in a ratio of about 1-3:1-3:1-7, and preferably in a ratio of about 3:3:5, for about 1 minute to 10 minutes. Alternatively, the solution may be sprayed onto the substrate 110, and the substrate 110 may be left for 1 minute to 10 minutes as it is.

Then, the substrate 110 is dried using a spin dry method or by an air blower emitting a gas such as nitrogen or argon.

This process causes a base —OH and an oxide —O to be induced onto the surface of the pixel conductors 81, 82, 191, and 193 and to improve the adhesion of the SAM 50.

Next, the surface of the pixel conductors 81, 82, 191, and 193 is secondly washed with a hydrophobic material such as isooctane and the like.

Then, surface treatment is performed on the pixel conductors 81, 82, 191, and 193 using a SAM material.

The SAM material has a functional group with high electronegativity on one terminal and a functional group having good reactivity to the pixel conductors 81, 82, 191, and 193 on the other terminal.

A phosphonic acid-based SAM material such as 4-chlorophenyl phosphonic acid, 3-nitrophenyl phosphonic acid, or 2-chloroethyl phosphonic acid is dissolved in a mixed solvent of methanol and chloroform, making a solution having a concentration of about 5 to 30 mM, and preferably about 10 mM. It is desirable that the mixing ratio of methanol and chloroform is about 3:7.

Other examples of the SAM material include aryldihalophospate, substituted aryldihalophospate, arylsulfonyl halide, substituted arylsulfonyl halide, trihalophenylsilane, substituted trihalophenylsilane, and so on.

The substrate 110 is put into the prepared solution of the SAM material and the solvent for about 10 to 20 minutes. Alternatively, the prepared solution is sprayed on the substrate 110 and the substrate 110 is left for about 10 to 20 minutes.

Then, the surfaces of the pixel conductors 81, 82, 191 and 193 are rinsed with methanol and chloroform.

Resultantly, SAM 50, as shown in FIG. 16, is formed on the exposed surfaces of the gate insulator 144 and the pixel conductors 81, 82, 191, and 193.

Finally, an organic semiconductor 154 and a blocking member 184 are formed in the opening 186 using an inkjet print method, as shown in FIG. 4 and FIG. 5.

If the surface modification is performed before forming the bank 180, a SAM 50 is formed as shown in FIG. 6, and then the SAM 50 is further disposed between the bank 180 and the pixel conductors 193, 191.

As described above, a work function increases by forming a self-assembled monolayer on the surface of the pixel conductor, thereby improving the efficiency of the organic TFT array panel.

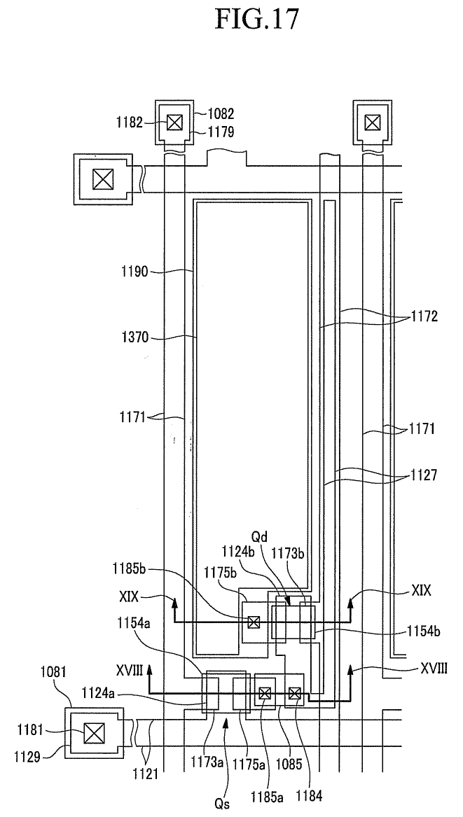

Hereinafter, an organic light emitting diode (“OLED”) display according to an exemplary embodiment of the present invention will be described with reference to FIG. 17 to FIG. 19.

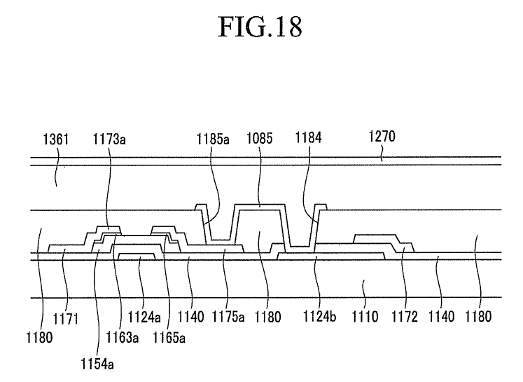

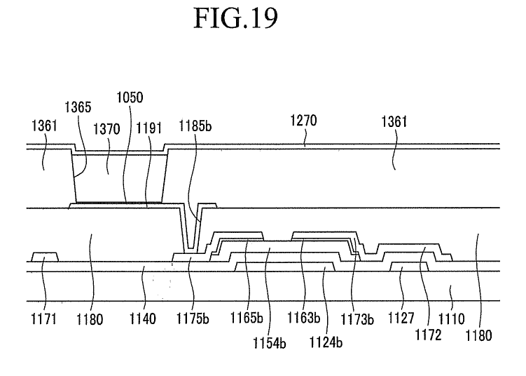

FIG. 17 is a layout view of an exemplary OLED display according to an exemplary embodiment of the present invention. FIG. 18 and FIG. 19 are cross-sectional views of the exemplary OLED display taken along lines XVIII-XVIII and XIX-XIX of FIG. 17, respectively.

A plurality of gate conductors including a plurality of gate lines 1121 having first control electrodes 1124a and a plurality of the second control electrodes 1124b are formed on an insulation substrate 1110 made of transparent glass or plastic.

The gate lines 1121 transfer gate signals and extend basically in a horizontal direction, such as a first direction. Each of the gate lines 1121 includes a wide end 1129 for connecting with other layers or external driving circuits. The first control electrodes 1124a extend upward from the gate lines 1121 towards adjacent gate lines 1121. If a gate driving circuit (not shown) for generating gate signals is integrated with the substrate 1110, the gate lines 1121 may extend to connect to the gate driving circuit directly.

The second control electrodes 1124b are separated from the gate lines 1121 and include storage electrodes 1127 extending to run downward, bend to the right, and run upward, such that the second control electrodes 1124b has a hook shape.

The gate conductors 1121 and 1124b may be made of an aluminum —Al group metal including Al or an Al alloy, a silver —Ag group metal including Ag or a Ag alloy, a copper —Cu group metal including Cu or a Cu alloy, a molybdenum —Mo group metal including Mo or a Mo alloy, chromium Cr, tantalum Ta, or titanium Ti. They may, however, have a multi-layered structure including two conductive layers (not shown) that have different physical properties from each other. In such a multi-layered structure, one of the two conductive layers may be made of a low-resistive metal to reduce voltage drop, such as an Al-group metal, a Ag-group metal, and a Cu-group metal, and the other conductive layer may be made of a material that has an excellent physical, chemical, and electrical contact characteristic with other materials, particularly with ITO and IZO, for example a Mo-group metal, chromium, tantalum, and titanium. Exemplary combinations may include a combination of a chromium lower layer and an aluminum (alloy) upper layer, and a combination of an aluminum (alloy) lower layer and a molybdenum (alloy) upper layer. While particular examples are presented, it should be understood that the gate conductors 1121 and 1124b may be made of various other metals or conductors.

The sides of the gate lines 1121 and the second control electrodes 1124b are inclined relative to the surface of the substrate 1110, and it is desirable that the inclination angle is about 30 to about 80 degrees.

A gate insulating layer 1140 made of silicon nitride (SiNₓ) or silicon oxide (SiOₓ) is formed on the gate conductors 1121 and 1124b and on exposed surfaces of the substrate 1110.

A plurality of island-shaped semiconductors 1154a and 1154b that are made of hydrogenated amorphous silicon (“a-Si”) or polysilicon are formed on the gate insulating layer 1140. The first and second semiconductors 1154a and 1154b are placed on the first and second control electrodes 1124a and 1124b, respectively.

A plurality of pairs of first ohmic contacts 1163a and 1165a and second ohmic contacts 1163b and 1165b are formed on the first and second semiconductors 1154a and 1154b, respectively. The ohmic contacts 1163a, 1163b, 1165a, and 1165b are island-shaped, and may be made of silicide or n+ hydrogenated a-Si in which an n-type impurity such as phosphorus is highly doped. The first ohmic contacts 1163a and 1165a form a pair to be disposed on the semiconductor 1154a, the second ohmic contacts 1163b and 1165b form a pair to be disposed on the second semiconductor 1154b.

A plurality of data conductors including a plurality of data lines 1171, a plurality of driving voltage lines 1172, and a plurality of the first and second output electrodes 1175a and 1175b are formed on the ohmic contacts 1163a, 1163b, 1165a, and 1165b and the gate insulating layer 1140.

The data lines 1171 transfer data signals and extend mainly in a vertical direction, a second direction, to cross the gate lines 1121. Each of the data lines 1171 has a plurality of the first input electrodes 1173a extending toward the first control electrodes 1124a, and partially overlapping the first control electrodes 1124a, and a wide end 1179 for connecting with other layers or external driving circuits. If a data driving circuit (not shown) for generating data signals is integrated with the substrate 1110, it may be directly connected to the data lines 1171.

The driving voltage lines 1172 transfer driving voltages and extend mainly in a vertical direction, the second direction, to cross the gate lines 1121. Each of the driving voltage lines 1172 has a plurality of second input electrodes 1173b extending toward the second control electrodes 1124b, and partially overlapping the second control electrodes 1124b. The driving voltage lines 1172 overlap with the storage electrodes 1127, and they may connect with each other.

The first and second output electrodes 1175a and 1175b are separated from each other, and they are also separated from the data lines 1171 and the driving voltage lines 1172. The first input electrode 1173a and the first output electrode 1175a face each other with the first control electrode 1124a there between, and the second input electrode 1173b and the second output electrode 1175b face each other with the second control electrode 1124b there between.

It is desirable that the data conductors 1171, 1172, 1175a, and 1175b are made of a refractory metal such as molybdenum, chromium, tantalum, titanium, and alloys thereof, and have a multi-layered structure having a refractory metal layer (not shown) and a low-resistive conductive layer (not shown). An exemplary multilayer structure may be a dual-layer of a chromium or molybdenum (alloy) lower layer and an aluminum (alloy) upper layer, and a triple-layer of a molybdenum (alloy) lower layer, an aluminum (alloy) middle layer, and a molybdenum (alloy) upper layer. The data conductors 1171, 1172, 1175a, and 1175b, however, may be made of various other metals or conductors.

Like the gate conductors 1121 and 1124b, the sides of the data conductors 1171, 1172, 1175a, and 1175b are inclined relative to the surface of the substrate 1110, and it is desirable that the inclination angle is about 30 to about 80 degrees.

The ohmic contacts 1163a, 1163b, 1165a, and 1165b are disposed only between the semiconductors 1154a and 1154b and the data conductors 1171, 1172, 1175a, 1175b to reduce the contact resistance between them. The semiconductors 1154a and 1154b have regions that are not covered with the data conductors 1171, 1172, 1175a, and 1175b, such as the regions between the input electrodes 1173a and 1173b and the output electrodes 1175a and 1175b.

A passivation layer 1180 is formed on the data conductors 1171, 1172, 1175a, and 1175b, and the exposed regions of the semiconductors 1154a and 1154b, as well as on exposed portions of the gate insulating layer 140. The passivation layer 1180 is made of an inorganic insulator such as silicon nitride or silicon oxide, an organic insulator, and a low-dielectric insulator. It is preferable that the dielectric constant of the organic insulator and low-dielectric insulator is less than 4.0. Examples may be a-Si:C:O or a-Si:O:F formed by plasma enhanced chemical vapor deposition (“PECVD”). A passivation layer 1180 can be one having photosensitivity among organic insulators, and the surface of the passivation layer 1180 can be flattened. The passivation layer 1180, however, may have a dual-layered structure composed of a lower inorganic layer and an upper organic layer to protect the exposed regions of the semiconductors 1154a and 1154b and provide an excellent insulating characteristic of the organic layers.

A plurality of contact holes 1182, 1185a, and 1185b are formed through the passivation layer 1180 to expose ends 1179 of the data lines 1171 and the first and second output electrodes 1175a and 1175b, respectively. Also, a plurality of contact holes 1181 and 1184 are formed through the passivation layer 1180 and the insulating layer 1140 to expose ends 1129 of the gate lines 1121 and the second input electrode 1124b.

A plurality of pixel electrodes 1191, a plurality of connecting members 1085, and a plurality of contact assistants 1081 and 1082 are formed on the passivation layer 1180.

The pixel electrodes 1191, the plurality of connecting members 1085, and the plurality of contact assistants 1081 and 1082 may be made of a transparent conductive material such as ITO or IZO.

The pixel electrodes 1191 are physically and electrically connected to the second output electrodes 1175b through the contact holes 1185b. The connecting members 1085 are connected to the second control electrodes 1124b and the first output electrodes 1175a through the contact holes 1184 and 1185a.

The contact assistants 1081 and 1082 are connected to the end 1129 of each gate line 1121 and the end 1179 of each data line 1171 through contact holes 1181 and 1182, respectively. The contact assistants 1081 and 1082 compensate the adhesive property between the ends 1179 and 1129 of the data and gate lines 1171 and 1121 and an external device, and protect the ends 1179 and 1129.

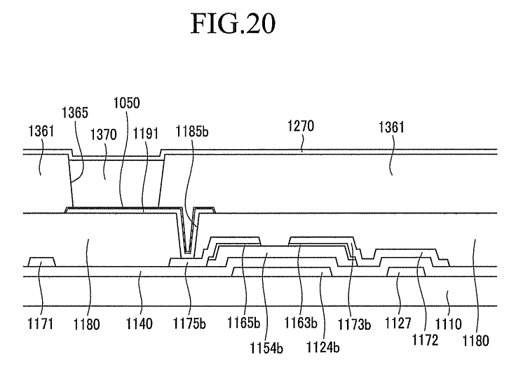

A SAM 1050 is formed on the pixel electrode 1191. Since the SAM 50 was previously described with reference to FIG. 1 to FIG. 3, a detailed description of the SAM 1050 will be omitted. In FIG. 19, the SAM 1050 is formed only on a predetermined area of the pixel electrode 1191. However, the SAM 1050 is formed on the entire pixel electrode 1191 in FIG. 20.

A partition 1361 is formed on the passivation layer 1180. The partition 1361 surrounds the edges of the pixel electrode 1191 like a bank, thereby defining an opening 1365, and is made of an organic insulator or an inorganic insulator. The partition 1361 may be made of a photoresist including a black pigment, in which case, the partition 1361 functions as a light blocking member, and the manufacturing process thereof is simple. In FIG. 19, the partition 1361 may be formed prior to forming the SAM 1050 on the pixel electrode 1191 such that the SAM 1050 is limited to the area of the pixel electrode 1191 exposed by the opening 1365, and in FIG. 20, the partition 1361 may be formed subsequent to forming the SAM 1050 on the pixel electrode 1191, such that the SAM 1050 is disposed between the pixel electrode 1191 and the partition 1361.

An organic light emitting member 1370 is formed on the SAM 1050 in the opening 1365 that is formed on the pixel electrode 1191 defined by the partition 1361. The organic light emitting member 1370 is made of an organic material that emits light of one of three primary colors of red, green, and blue. The OLED display displays a desired image through a spatial sum of primary color light emitted from the organic light emitting members 1370.

The organic light emitting member 1370 can have a multi-layered structure including an auxiliary layer (not shown) for improving the light efficiency of an emission layer beside the emitting layer that emits the light. The auxiliary layer may include an electron transport layer and a hole transport layer for balancing the electrons and holes, and an electron injecting layer and a hole injecting layer for enhancing electron and hole injection.

A common electrode 1270 is formed on the organic light emitting member 1370, and may be further formed on the partition 1361. The common electrode 1270 receives a common voltage Vss, and is made of a transparent conductive material such as ITO and IZO or a reflective metal including calcium Ca, barium Ba, magnesium Mg, aluminum Al, silver Ag, etc.

In the OLED display, the first control electrode 1124a connected to the gate line 1121, the first input electrode 1173a connected to the data line 1171, and the first output electrode 1175a form a switching TFT Qs with the first semiconductor 1154a. The channel of the switching TFT Qs is formed on the first semiconductor 1154a between the first input electrode 1173a and the first output electrode 1175a. The second control electrode 1124b connected to the first output electrode 1175a, the second input electrode 1173b connected to the driving voltage line 1172, and the second output electrode 1175b connected to the pixel electrode 191 form a driving TFT Qd with the second semiconductor 1154b. The channel of the driving TFT Qd is formed on the second semiconductor 1154b between the second input electrode 1173b and the second output electrode 1175b. The pixel electrode 1191, the organic light emitting member 1370, and the common electrode 1270 form an organic light emitting device LD. The pixel electrode 1191 becomes an anode, and the common electrode 1270 becomes a cathode. The storage electrode 1127 and the driving voltage line 1172, which overlap each other, form a storage capacitor Cst.

Such an OLED display displays an image by emitting light in an upward direction from the substrate 1110 or in a downward direction from the substrate 1110. An opaque pixel electrode 1191 and a transparent common electrode 1270 are applied to a top emission type of OLED display that displays an image in an upward direction from the substrate 1110. A transparent pixel electrode 1191 and an opaque common electrode 1270 are applied to a bottom emission type of OLED display that displays an image in a downward direction from the substrate 1110.

If semiconductors 1154a and 1154b are made of polysilicon, an intrinsic region (not shown) facing the control electrodes 1124a and 1124b and extrinsic regions (not shown) disposed at both sides of the intrinsic region are included. The extrinsic region is electrically connected to the input electrodes 1173a and 1173b and output electrodes 1175a and 1175b. The ohmic contacts 1163a, 1163b, 1165a, and 165b can be omitted.

In an alternative embodiment, the control electrodes 1124a and 1124b can be placed on the semiconductors 1154a and 1154b. In this case, the insulating layer 1140 is located between the semiconductors 1154a and 1154b and the control electrodes 1124a and 1124b. The data conductors 1171, 1172, 1173b, and 1175b are placed on the insulating layer 1140 and are electrically connected to the semiconductors 1154a and 1154b through a contact hole (not shown) formed on the insulating layer 1140. Alternatively, the data conductors 1171, 1172, 1173b, and 1175b can be placed under the semiconductors 1154a and 1154b and be electrically connected to the semiconductors 1154a and 1154b.

As described above, a work function of the pixel electrode 1191 can increase by forming the SAM 1050 on the surface of the pixel electrode 1191, thereby improving the display efficiency of the OLED: display.

The switching TFT Qs and the driving TFT Qd in the OLED display shown in FIG. 17 to FIG. 20 can be made identically to, or substantially the same as, the organic TFT shown in FIG. 4 to FIG. 6.

The OLED displays in FIG. 17 to FIG. 20 are only exemplary embodiments, and the present invention can also be applied to other embodiments of an OLED display.

As described above, a work function of an ITO thin film increases by activating the ITO thin film used as an electrode of an organic active layer and modifying the surface thereof. It facilitates hole injection to the elements including the organic active layer, for example a TFT or an OLED, thereby improving the efficiency of the element.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method for forming a contact of an organic active layer, the method comprising:
forming a transparent conductive oxide thin film on a substrate;
activating a surface of the oxide thin film by inducing a base —OH and an oxide —O;
washing the oxide thin film with a hydrophobic material;
forming a self-assembled monolayer on the oxide thin film; and
forming an organic active layer on the self-assembled monolayer.

2. The method of claim 1, further comprising rinsing the substrate after forming the self-assembled monolayer and before forming the organic active layer.

3. The method of claim 2, wherein, in washing the oxide thin film, a mixed solution of methanol and chloroform is used.

4. The method of claim 1, wherein forming a transparent conductive oxide thin film includes forming indium tin oxide on the substrate.

5. The method of claim 4, wherein, in activating the surface, the substrate is processed by a mixed solution of hydrogen peroxide (H₂O₂), ammonia (NH₃), and distilled water (H₂O) in a mixing ratio of about 1-3:1-3:1-7.

6. The method of claim 5, wherein processing the substrate includes immersing the substrate in the mixed solution.

7. The method of claim 6, wherein immersing the substrate in the mixed solution includes immersing the substrate in the mixed solution for about 1 minute to 10 minutes.

8. The method of claim 5, wherein processing the substrate includes spreading the mixed solution on the substrate.

9. The method of claim 8, wherein processing the substrate further includes leaving the substrate with the mixed solution spread thereon for a time period within a range of about 1 to 10 minutes.

10. The method of claim 5, wherein the mixing ratio of hydrogen peroxide (H₂O₂), ammonia (NH₃), and distilled water (H₂O) is about 3:3:5.

11. The method of claim 4, wherein the hydrophobic material is isooctane.

12. The method of claim 1, wherein forming the self-assembled monolayer includes forming a solution formed by dissolving a self-assembled monolayer material with a terminal having a functional group of high electronegativity and another terminal having a functional group of high reactivity on a conductive oxide thin film in a mixed solvent of methanol and chloroform, and immersing the substrate in the solution.

13. The method of claim 12, wherein a mixing ratio of methanol and chloroform in the mixed solvent of methanol and chloroform is about 3:7.

14. The method of claim 12, wherein a concentration of the solution is about 5 mM to 30 mM.

15. The method of claim 12, wherein the self-assembled monolayer material includes at least one of 4-chlorophenyl phosphonic acid, 3-nitrophenyl phosphonic acid, and 2-chloroethyl phosphonic acid.

16. The method of claim 12, wherein the self-assembled monolayer material includes at least one of aryldihalophospate, substituted aryldihalophospate, arylsulfonyl halide, substituted arylsulfonyl halide, trihalophenylsilane, and substituted trihalophenylsilane.

17. The method of claim 1, wherein a work function of the oxide thin film formed with the self-assembled monolayer is about 5.2 eV to 5.5 eV.

18. An organic thin film transistor comprising:
a substrate;
a gate electrode formed on the substrate;
a gate insulator formed on the gate electrode;
an input electrode formed on the gate insulator;
an output electrode facing the input electrode on the gate insulator;
a self-assembled monolayer formed on a surface of the input electrode and the output electrode;
an organic semiconductor formed on the input electrode, the output electrode and the gate insulator;
wherein a work function of the input electrode and the output electrode with the self-assembled monolayer is about 5.2 eV to 5.5 eV.

19. The organic thin film transistor of claim 18, wherein the self-assembled monolayer includes at least one of 4-chlorophenyl phosphonic acid, 3-nitrophenyl phosphonic acid, and 2-chloroethyl phosphonic acid.

20. The organic thin film transistor of claim 18, wherein the self-assembled monolayer material includes at least one of aryldihalophospate, substituted aryldihalophospate, arylsulfonyl halide, substituted arylsulfonyl halide, trihalophenylsilane, and substituted trihalophenylsilane.
